(19) United States
(12) Patent Application Publication
(10) Pub. No.: US 2020/0214167 A1
(43) Pub. Date: Jul. 2, 2020

(54) HEAT DISSIPATION STRUCTURE AND HEAT DISSIPATION METHOD OF ELECTRONIC DEVICE

(71) Applicant: PANASONIC INTELLECTUAL PROPERTY MANAGEMENT CO., LTD., Osaka (JP)

(72) Inventors: Toshinobu HATANO, Kanagawa (JP); Makoto SAITO, Kanagawa (JP); Ken NAKAMURA, Kanagawa (JP)

(73) Assignee: PANASONIC INTELLECTUAL PROPERTY MANAGEMENT CO., LTD., Osaka (JP)

(21) Appl. No.: 16/723,526

(22) Filed: Dec. 20, 2019

(30) Foreign Application Priority Data
Dec. 27, 2018 (JP) 2018-244959

(51) Int. Cl. H05K 7/20

(52) U.S. Cl. CPC H05K 7/205; H04N 5/2252; H05K 7/20454

(57) ABSTRACT

A heat dissipation structure of an electronic device, includes: a metal case; and a rigid flexible board housed in the metal case and comprising a rigid portion and a flex portion connected to the rigid portion. At least part of the flex portion contacts the metal case to allow heat generated by an electronic component mounted on the rigid portion to be released to the metal case.

### FIELD

The present disclosure relates to a heat dissipation structure and a heat dissipation method employed in an electronic device such as a camera to dissipate heat generated inside a body of the electronic device to outside the electronic device.

### BACKGROUND

In the automobile industry, sensing technologies for realizing autonomous drive are now being developed actively. Cameras which are typical image information input devices are naturally desired to be compact and are, furthermore, desired to be able to be installed in a vehicle freely in the manner of disposition without the need for considering distances from and directions with respect to other electronic devices and an antenna device with importance attached to the vehicle design.

As for the camera image signal transmission method, a transition is now being made from the analog video signal output method to the high-speed serial digital signal output method which can output high resolution image information stably. In connection with the high-speed digital data transmission, low-noise, noise-resistant designing in a radio frequency range is important in camera application systems. On the other hand, not only are cameras required to be increased in operation quality under a vehicle high-temperature environment but also countermeasures against heat that relate to temperature increase inside a camera during actual operation of electric circuits are now an important issue together with low-noise, noise-resistant designing.

JP-B-5427076 discloses an example heat dissipation structure of a camera. The camera disclosed in JP-B-5427076 includes: a CCD (charge-coupled device) heat dissipation plate which is attached to a CCD fixing plate (that holds a CCD) and receives heat generated by the CCD; and a heat conduction member A for dissipating, to a front frame, the heat that the CCD heat dissipation plate receives from the CCD. The camera is also includes a second heat dissipation plate which contacts heat generation components on a CCD control board mounted with the CCD and the heat generation components and releases heat generated by the heat generation components and a heat conduction member B for dissipating, to the front frame, the heat released from the heat generation components to the second heat dissipation plate. In this manner, heat generated by the CCD and heat generated by the heat generation components are dissipated along different routes, whereby a heat dissipation structure can be obtained that can dissipate both of heat generated by the CCD and heat generated by the components mounted on the board and lower the mechanical load on the board.

### SUMMARY

To obtain an ideal shielding effect capable of realizing low-noise, noise-resistant performance, cameras are required to be provided with a contact structure capable of further improvement in the electrical characteristics of a connector-shield connection portion and to be improved in the shape, manner of disposition, and support structure of a shield case. In cameras, it is required to not only implement a shape and structure for obtaining an ideal shielding effect but also provide a structure for allowing escape, to outside the device, of heat that is generated by electronic components mounted on boards provided inside the camera during operation of electric circuits.

In camera designing, a technique for incorporating components dedicated to heat dissipation into the camera as inside components and having a manufacturing process include steps for incorporating those components increases not only the cost of the camera due to increase in the number of components but also the manufacturing cost because addition of new assembling steps requires additional items, considerations, etc. in process designing, management, maintenance, and tests. The above-described camera disclosed in JP-B-5427076 includes, as heat dissipation members, the dedicated heat dissipation plates (CCD heat dissipation plate and second heat dissipation plate), the heat dissipation sheets (heat conduction members A and B), etc. However, this camera is considered to be increased in manufacturing cost because it is absent from by-products-producing approaches intended for ease of assembling and a shielding effect.

The present disclosure has been made in view of the above circumstances, and an object thereof is to provide a heat dissipation structure and a heat dissipation method of an electronic device capable of dissipating heat generated on an internal board to outside the device efficiently while realizing a shielding effect.

The disclosure provides a heat dissipation structure of an electronic device, including: a metal case; and a rigid flexible board housed in the metal case and including a rigid portion and a flex portion connected to the rigid portion, wherein at least part of the flex portion contacts the metal case to allow heat generated by an electronic component mounted on the rigid portion to be released to the metal case.

The disclosure further provides a heat dissipation method of an electronic device, including: housing a rigid flexible board including a rigid portion and a flex portion connected to the rigid portion in a metal case such that at least part of the flex portion contacts the metal case; and dissipating heat generated by an electronic component mounted on the rigid portion to the metal case via the flex portion.

According to the present disclosure, it is possible to release heat generated on an internal board of an electronic device to outside the device efficiently while realizing a shielding effect of the electronic device.

### BRIEF DESCRIPTION OF DRAWINGS

FIG. 1 shows a configuration of a camera according to an embodiment of the present disclosure.

FIG. 2 is a schematic diagram showing how heat transfers inside the camera according to the embodiment.

FIG. 3 shows the configuration of a camera including a rigid flexible board having one rigid portion as an application example of the camera according to the embodiment.

FIG. 4 shows the configuration of a camera including a camera body made of metal and a rigid flexible board having two rigid portions as another application example of the camera according to the embodiment.

FIG. 5 shows the configuration of a camera including a camera body made of metal and a rigid flexible board having one rigid portion as a further application example of the camera according to the embodiment.

FIG. 6 shows an example of a rigid flexible board in which two rigid portions are connected by a flex portion.

FIG. 7 shows an example of a rigid flexible board in which three rigid portions are connected by two flex portions.

FIG. 8 shows a configuration of a camera employing heat conduction members.

### DETAILED DESCRIPTION

A preferred embodiment of the present disclosure will be hereinafter described in detail with reference to the drawings.

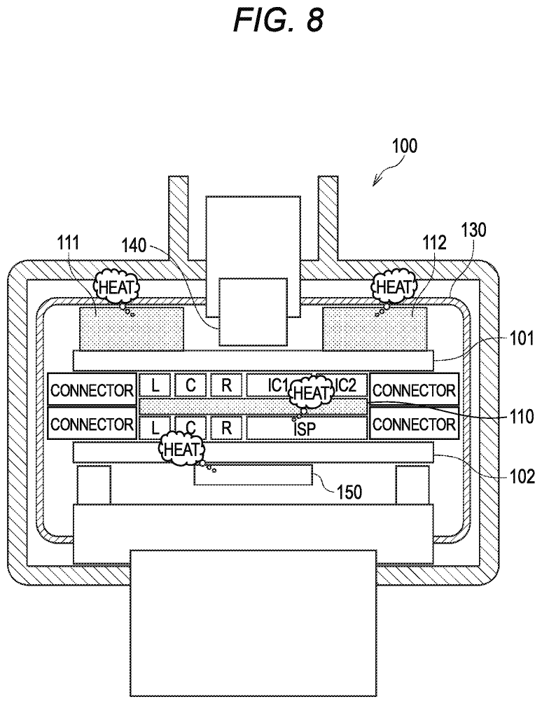

At first, a camera 100 employing heat conduction members is described with reference to FIG. 8. In the camera 100, a cool sheet 110 is provided between two multilayer circuit boards 101 and 102 and cool sheets 111 and 112 are provided between the upper multilayer circuit board 101 and the inner surface of a top plate portion of a metal shield case 130. The two multilayer circuit boards 101 and 102 are disposed in such a manner that their surfaces mounted with many electronic components oppose each other, and the cool sheet 110 is disposed between those surfaces. A board-side connector 140 is mounted at the center on the surface, opposite to its electronic components mounting surface, of the upper multilayer circuit board 101 and the cool sheets 111 and 112 are disposed on the two respective sides of the board-side connector 140. Heat generated by the electronic components mounted on the lower multilayer circuit board 102 (heat mainly generated by an image processor ISP (image signal processor) and a sensor 150 such as a CCD or a CMOS (complementary metal-oxide-semiconductor) sensor) is transmitted to the upper multilayer circuit board 101 via the cool sheet 110 and is released to the metal shield case 130 via the cool sheets 111 and 112 together with heat generated by the electronic components mounted on the upper multilayer circuit board 101 (heat mainly generated by integrated circuits IC1 and IC2). In FIG. 8, symbols L, C, and

R represent coils, capacitors, and resistors, respectively.

In the above-described configuration, the cool sheets 110, 111, 112 as dedicated heat dissipation members are provided in the camera 100, which results in increase of manufacturing cost due to increase of number of elements and manufacturing processes, similar to the camera of the background art.

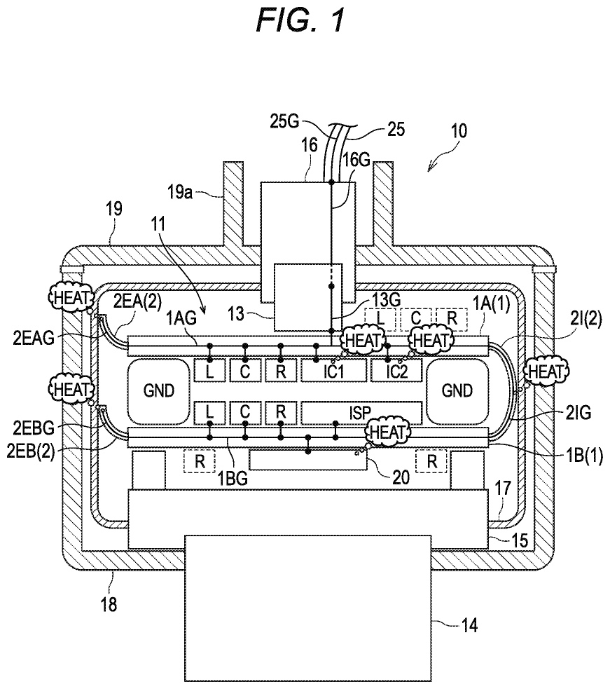

FIG. 1 shows the configuration of a camera (electronic device) 10 according to the embodiment of the disclosure. As shown in FIG. 1, the camera 10 according to the embodiment includes a rigid flexible board 11 including a rigid portion 1 and a flex portion 2 connected to the rigid portion 1. The rigid portion 1 includes a first rigid portion 1A and a second rigid portion 1B which oppose each other. The flex portion 2 includes end flex portions 2EA, 2EB. The camera 10 further includes: a board-side shield connector 13 (an example of a metal shield connector) which is mounted at a substantially central portion of a surface of the rigid flexible board 11 which is opposite to the surface opposing the second rigid portion 1B; a base 15 including one surface which supports the rigid flexible board 11 and another surface which is opposite to the one surface and supports a lens 14; a metal shield case 17 (an example of a metal case) including a top plate portion having a hole for insertion of a case-side shield connector 16 (an example of a metal shield connector) to be connected to the board-side shield connector 13 and a bottom plate portion having a hole for insertion of the base 15, and the metal shield case 17 configured to house the rigid flexible board 11, the base 15, and the board-side shield connector 13; a non-metal camera barrel case 18 which is open at the top, includes a bottom plate portion having a hole for insertion of the lens 14, and is configured to house the metal shield case 17; and a non-metal camera rear case 19 which has a center hole for insertion of the case-side shield connector 16, includes a cylindrical connector protection wall 19a around the hole, is in close contact with the opening surface of the camera barrel case 18, and closes the opening of the camera barrel case 18.

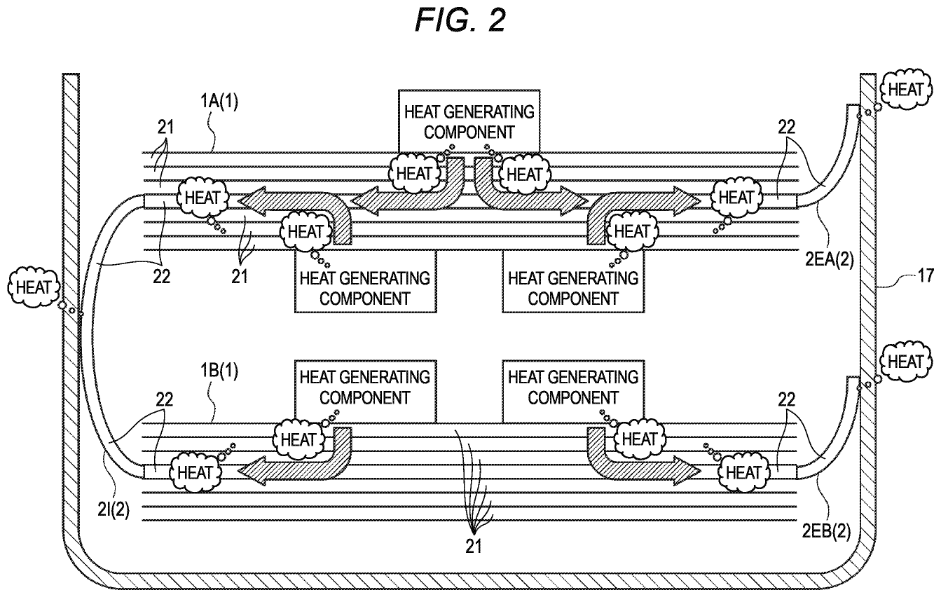

The term “rigid flexible board” as used herein means a board having advantages of a rigid board and a flexible board such as being high in the ease of mounting of components and being able to be disposed three-dimensionally by being bent. Usually, the rigid flexible board includes a rigid portion on which electronic components etc. are mountable and a flex portion that is bendable. As shown in FIG. 2, the rigid portion 1 is formed by a multi-layer structure in which a flexible layer 22 and a rigid layer 21 that are laminated and connected to each other using a through-hole. The flexible layer 22 is made of a flexible material that is bendable such as polyimide, and the rigid layer 21 is made of a rigid material such as glass epoxy resin. To implement a high-density circuit or the like, a build-up method is applied to the rigid portion. The flex portion 2 is formed by only the flexible layer 21 extending from the rigid portion 1 so as to be bendable. If the flex portion 2 includes the flexible layer 21 having three or more conductor layers, its bendability becomes extremely low substantially, and hence the flexible layers 21 are divided into plural units each having two layers (or one layer in the case where a longer flex life is required). Since a rigid portion 1 and a flexible portion 2 are integrated with each other, no connector for connecting the rigid portion 1 and the flexible portion is necessary. That is, the rigid board and the flexible board can be connected to each other without using a connector.

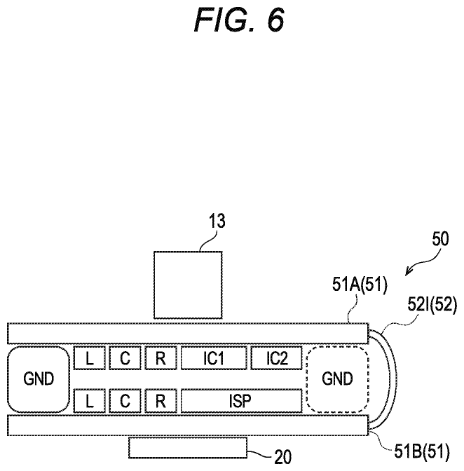

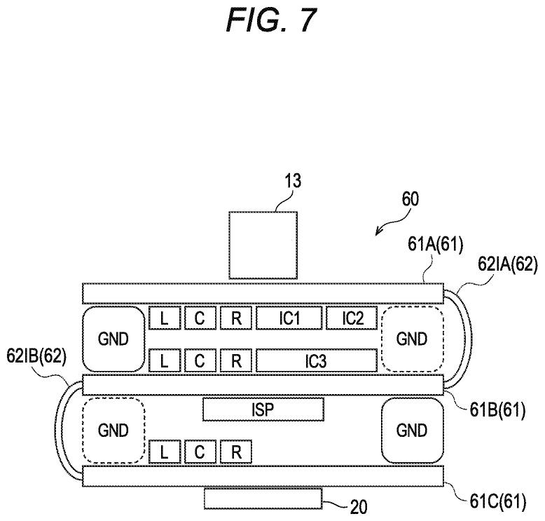

FIG. 6 shows an example of a rigid flexible board 50 in which two rigid portions 51 are connected to each other by a flex portion 52. As shown in FIG. 6, the rigid portion 51 includes a first rigid portion 51A and a second rigid portion 51B, and the flex portion 52 includes an intermediate flex portion 52I. The first rigid portion 51 and the second rigid portion 51B are connected to each other by the intermediate flex portion 52I. FIG. 7 shows an example of a rigid flexible board 60 in which three rigid flexible portions are connected together by two flex portions. As shown in FIG. 7, the rigid portion 61 includes a first rigid portion 61A, a second rigid portion 61B and a third rigid portion 61C, and the flex portion 62 includes a first intermediate flex portion 62IA and a second intermediate flex portion 62IB. The first rigid portion 61A and the second rigid portion 61B are connected to each other by the first intermediate flex portion 62IA, and the second rigid portion 61B and the third rigid portion 61C are connected to each other by the second intermediate flex portion 62IB.

As described above, the rigid flexible board can be constructed in a variety of forms; it has become possible technically to implement all interconnections of one electronic device by means of one multilayer rigid flexible board. The rigid flexible boards having various shapes such as of a folding type and a book binder type have been manufactured.

The rigid flexible board 11 includes a hard, rigid portion 1 on which electronic components, etc., are mountable, and a bendable flex portion 2. The electronic components may be mounted on one or both surfaces of the rigid portion 1. In the present embodiment, on one surface (the bottom surface in FIG. 1) of the first rigid portion 1A, a coil L, a capacitor C, a resistor R, and integrated circuits IC1 and IC2 such as power supply IC are mounted, and on the other surface (the top surface in FIG. 1), a coil L, a capacitor C, a resistor R, and the board-side shield connector 13 are mounted. On one surface (the bottom surface in FIG. 1) of the second rigid portion 1B, resistors R and a sensor 20 such as a CCD or a CMOS are mounted, and on the other surface (the top surface in FIG. 1) of the second rigid portion 1B, a coil L, a capacitor C, a resistor R, and an image processor ISP are mounted.

Signal transmission between the first rigid portion 1A and the second rigid portion 1B is performed via the intermediate flex portion 2I. The intermediate flex portion 2I is provided at one end surface of the first rigid portion 1A and the second rigid portion 1B to connect them. The intermediate flex portion 2I includes a ground line for signal transmission. In the present embodiment, the ground line is formed by a metal solid printed ground wiring 2IG made of metal material having high heat dissipation property such as copper foil.

The intermediate flex portion 2I of the rigid flexible board 11 has a length to bring a substantially central portion of the intermediate flex portion 2I into contact with an inner surface of the metal shield case 17 when the rigid flexible board 11 is housed in the metal shield case 17 in a state in which the intermediate flex portion 2I connects the first rigid portion 1A and the second rigid portion 1B. That is, the intermediate flex portion 2I has a physical shape to be bent into a C shape and bring a top of the C shape into contact with the inner surface of the metal shield case 17 when the rigid flexible board 11 is housed in the metal shield case 17 in a state in which the intermediate flex portion 2I connects the first rigid portion 1A and the second rigid portion 1B.

Since part (the top portion of the C shape) of the intermediate flex portion 2I of the rigid flexible board 11 contacts the inner surface of the metal shield case 17, heat generated by the various electronic components mounted on the first rigid portion 1A (mainly heat generated by the integrated circuits IC1 and IC2) and heat generated by the various electronic components mounted on the second rigid portion 1B (mainly heat generated by the image processor ISP and the sensor 20) are transmitted to the metal shield case 17. That is, the heat generated by the various electronic components is allowed to escape to the metal shield case 17.

The intermediate flex portion 2I of the rigid flexible board 11 mainly serves for signal transmission, it is also used for escape of heat generated by the electronic components. The efficiency of escape of heat can be increased by making a metal solid printed ground wiring contained in the intermediate flex portion 2I wider than usual. If the intermediate flex portion 2I is dedicated to escape of heat (i.e., not used for signal transmission), the metal solid printed ground wiring can be made even wider, and the efficiency of escape of heat can thereby be increased further.

The rigid flexible board 11 of the camera 10 according to the embodiment includes, in addition to the intermediate flex portion 2I for signal transmission and heat dissipation, the first and second end flex portions 2EA, 2EB for heat dissipation which are provided at the first rigid portion 1A and the second rigid portion 1B, respectively. That is, the first end flex portion 2EA for heat dissipation is connected to the first rigid portion 1A, and the second end flex portion 2EB for heat dissipation is connected to the second rigid portion 1B. The first end flex portion 2EA is provided at an end surface of the first rigid portion 1A which is opposite to the end surface of the first rigid portion 1A at which the intermediate flex portion 2I of the rigid flexible board 11 is provided. The second end flex portion 2EB is provided at an end surface of the second rigid portion 1B which corresponds to the end surface of the rigid portion 1A at which the first end flex portion 2EA is provided. However, the second end flex portion 2EB need not always be provided at the end surface of the second rigid portion 1B corresponding to the end surface of the first rigid portion 1A at which the intermediate flex portion 2I is provided. That is, a first end of each of the first and second end flex portions 2EA, 2EB is provided at an end surface of corresponding one of the first and second rigid portions 1A, 1B, and a second end of each of the first and second end flex portions 2EA, 2EB is a free end.

The first end flex portion 2EA and the second end flex portion 2EB include wide metal solid printed ground wirings 2EAG, 2EBG, respectively, and have a physical shape (length) to bring the tip portion of the free ends into surface-to-surface contact with the inner surface of the metal shield case 17 when the camera 10 is assembled. The first end flex portion 2EA is provided to allow heat generated by the various electronic components mounted on the first rigid portion 1A (mainly heat generated by the integrated circuits IC1 and IC2) to escape to the metal shield case 17. The first rigid portion 1A includes a metal solid printed ground wiring 1AG that is connected to the metal solid printed ground wiring 2EAG of the first end flex portion 2EA, and heat generated by the various electronic components is transmitted to the metal shield case 17 via these metal solid printed ground lines 1AG, 2EAG.

The second end flex portion 2EB is provided to allow heat generated by the various electronic components mounted on the second rigid portion 1B (mainly heat generated by the image processor ISP and the sensor 20) to escape to the metal shield case 17. The second rigid portion 1B of the rigid flexible board 11 also includes a metal solid printed ground wiring 1BG that is connected to the metal solid printed ground wiring 2EBG of the second end flex portion 2EB, and heat generated by the various electronic components is transmitted to the metal shield case 17 via the metal solid printed ground wirings 1BG, 2EBG.

FIG. 2 is a schematic diagram showing how heat transfers inside the camera 10. Although FIG. 2 shows the positional relationship between the intermediate flex portion 2I and the first and second end flex portions 2EA and 2EB are opposite to that shown in FIG. 1, the manner of heat transfer remains the same. As shown in FIG. 2, heat generated by the heat generation components mounted on both surfaces of the first rigid portion 1A is transmitted to the metal shield case 17 via the intermediate flex portion 2I and the first end flex portion 2EA. Heat generated by the heat generation components mounted on one surface of the second rigid portion 1B is transmitted to the metal shield case 17 via the intermediate flex portion 2I and the second end flex portion 2EB.

Heat that is generated on the rigid flexible board 11 and transmitted to the metal shield case 17 is emitted to the external air after passing through the board-side shield connector 13, the case-side shield connector 16, and a shield cable 25 connected to the case-side shield connector 16 in this order. When the case-side shield connector 16 is connected to the board-side shield connector 13, a metal ground contact portion 16G of the case-side shield connector 16 and a metal ground contact portion 13G of the board-side shield connector 13 are connected to each other. Since a ground line 25G of the shield cable 25 is connected to the metal ground contact portion 16G of the case-side shield connector 16, heat that has been transmitted to the metal shield case 17 is transmitted to the metal ground contact portion 13G of the board-side shield connector 13, the metal ground contact portion 16G of the case-side shield connector 16, and the ground line 25G of the shield cable 25 in this order.

Further, the heat generated on the first rigid portion 1A is also directly transmitted from the meal ground contact portion 13G of the board-side shield connector 13 to the meal ground contact portion 16G of the case-side shield connector 16, then transmitted to the ground line 25G of the shield cable 25, and finally emitted to the external air.

As described above, heat generated by the various electronic components mounted on the first rigid portion 1A and the second rigid portion 1B is emitted from the camera 10 to the external air efficiently.

In the camera 10 according to the embodiment, the rigid flexible board 11 are used as a board on which the electronic components are mounted. The intermediate flex portion 2I which is provided at one end surface of the first rigid portion 1A is connected to one end surface of the second rigid portion 1B to enable signal transfer between the first rigid portion 1A and the second rigid portion 1B. A central portion of the intermediate flex portion 2I contacts the inner surface of the metal shield case 17 which houses the rigid flexible board 11. The first end flex portion 2EA dedicated to heat dissipation which is provided for an end surface of the first rigid portion 1A which is different from the above one end surface, contacts the inner surface of the metal shield case 17, and the second end flex portion 2EB dedicated to heat dissipation which is provided at an end surface of the second rigid portion 1B which corresponds to the end surface of the first rigid portion 1A at which the intermediate flex portion 2I is provided also contacts the inner surface of the metal shield case 17. With this configuration, heat generated by the various electronic components mounted on the first rigid portion 1A and the second rigid portion 1B is allowed to escape to the metal shield case 17.

Furthermore, since the camera 10 includes the board-side shield connector 13 having the metal ground contact portion 13G electrically connected to the metal shield case 17 and the case-side shield connector 16 having the metal ground contact portion 16G electrically connected to the metal ground contact portion 13G of the board-side shield connector 13, heat transmitted to the metal shield case 17 is allowed to escape to the shield cable 25 that is connected to the case-side shield connector 16.

Consequently, heat generated on the first rigid portion 1A and the second rigid portion 1B can be emitted to the external air efficiently while ease of assembling and a shielding effect of the camera 10 are realized.

The camera 10 according to the above-described embodiment includes two rigid portions 1 (the first rigid portion 1A and the second rigid portion 1B). On the other hand, in a case in which the rigid flexible board has a configuration of including one rigid portion, flex portion for connecting the two rigid portions (corresponding to the intermediate flex portion 2I) is not necessary, and only flex portions dedicated to heat dissipation (corresponding to the first and second end flex portions 2EA and 2EB) are provided for two respective end surfaces of the one rigid portion.

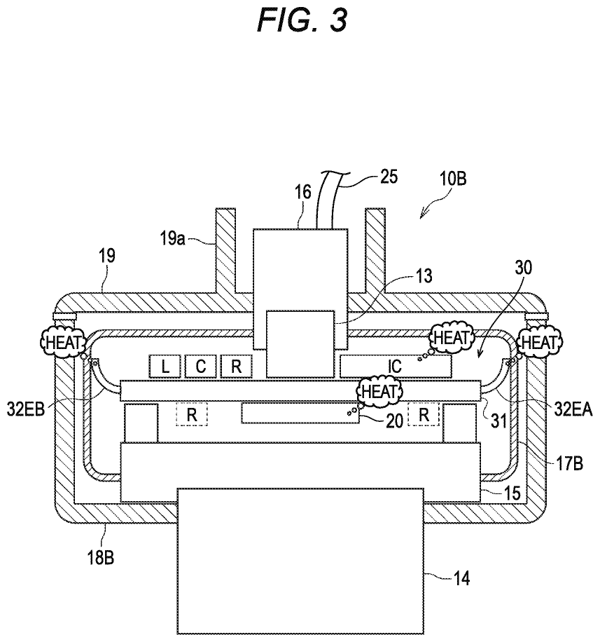

FIG. 3 shows the configuration of such an example of a camera 10B. In FIG. 3, elements having the same elements in the camera 10 shown in FIG. 1 are given the same reference symbols as the latter. A rigid flexible board 30 of the camera 10B shown in FIG. 3 includes one rigid portion 31, and end flex portions 32EA and 32EB dedicated to heat dissipation and provided at two respective end surfaces of the rigid portion 31 are both in contact with the inner surface of a metal shield case 17B. Heat generated by the various electronic components mounted on the rigid portion 31 is transmitted to the metal shield case 17B via the end flex portions 32EA and 32EB and then emitted to the external air via the shield cable 25 connected to the case-side shield connector 16. Since only one rigid portion 31 is housed in a camera barrel case 18B, the camera barrel case 18B is shallower than the camera barrel case 18 shown in FIG. 1. Each of the rigid portion 31 and the end flex portions 32EA, 32EB includes a metal solid printed ground wiring similar to the embodiment shown in FIG. 1.

The camera body (i.e., the camera barrel case 18 and the camera rear case 19) of the camera 10 according to the above-described embodiment is made of a non-metal material. On the other hand, where the camera body is made of a metal, the metal shield case 17 becomes unnecessary, and the flex portion 2 in the camera 10 may direct contact the camera body.

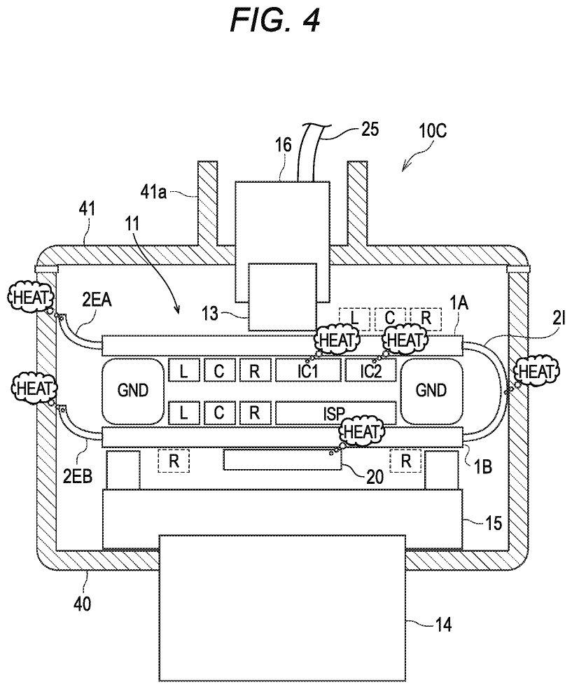

FIG. 4 shows the configuration of such an example of a camera 10C. In FIG. 4, elements having the same elements in the camera 10 shown in FIG. 1 are given the same reference symbols as the latter. As shown in FIG. 4, each of the intermediate flex portion 2I and the first and second end flex portions 2EA, 2EB contacts a camera barrel case 40 (an example of a metal case) which is made of metal and which has approximately the same shape as the camera barrel case 18 shown in FIG. 1. A camera rear case 41 (an example of a metal case) which is made of metal and which closes the opening of the camera barrel case 40 and a connector protection wall 41a which protects the case-side shield connector 16 also have approximately the same shapes as the camera rear case 19 and the connector protection wall 19a shown in FIG. 1, respectively. Since the camera barrel case 40 is connected to the metal ground contact portion 16G (see FIG. 1) of the case-side shield connector 16, heat generated by the various electronic components mounted on the first rigid portion 1A and the second rigid portion 1B is emitted to the external air via the shield cable 25 connected to the case-side shield connector 16. Further, the camera barrel case 40 made of metal and the camera rear case 41 made of metal provides the shield effect similar to the metal shield case 17 of the embodiment shown in FIG. 1.

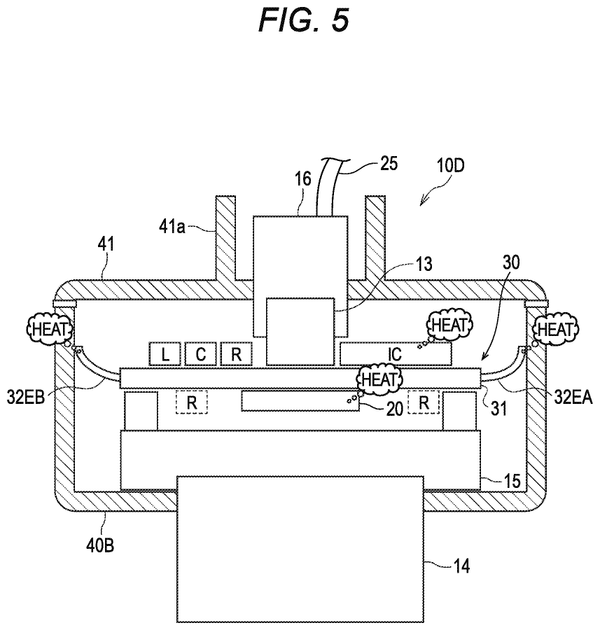

In a case where a rigid flexible board including only one rigid portion (rigid portion 31) is housed in the camera barrel case 40 made of metal, flex portions dedicated to heat dissipation and provided at two end surfaces of the rigid portion contact the inner surface of the camera barrel case 40. FIG. 5 shows the interior configuration of such as example of a camera 10D. In FIG. 5, elements having the same elements in the camera 10 shown in FIG. 1 are given the same reference symbols as the latter. In the camera 10D shown in FIG. 5, the end flex portions 32EA and 32EB provided at the two respective end surfaces of the rigid portion 31 contact an inner surface of a camera barrel case 40B (an example of a metal case). Since only one rigid portion 31 is housed in the camera barrel case 40B, the camera barrel case 40B is shallower than the camera barrel case 40 shown in FIG. 4.

The cameras 10, 10B, 10C, and 10D are explained as exemplified embodiments of an electronic device of the present disclosure. However, the present disclosure is not limited thereto, and may also be applied to electronic devices other than a camera.

While various embodiments have been described herein above, it is to be appreciated that various changes in form and detail may be made without departing from the spirit and scope of the invention(s) presently or hereafter claimed.

The present disclosure is useful as a heat dissipation structure and a heat dissipation method of an electronic device capable of dissipating heat generated on an internal board to outside the device efficiently.

The disclosure provides a heat dissipation structure of an electronic device, including: a metal case; and a rigid flexible board housed in the metal case and including a rigid portion and a flex portion connected to the rigid portion, wherein at least part of the flex portion contacts the metal case to allow heat generated by an electronic component mounted on the rigid portion to be released to the metal case.

With this configuration, heat generated by the electronic component mounted on the rigid portion of the rigid flexible board can be released to the metal case from the flex portion. Furthermore, the metal case provides a shielding effect.

In the heat dissipation structure, the flex portion may have a physical shape to bring the at least part of the flex portion into contact with the metal case when the electronic device is assembled.

With this configuration, since the flex portion has the physical shape to bring the at least part of the flex portion into contact with the metal case when the electronic device is assembled, the electronic device can be assembled easily by performing setting, mounting, and assembling work utilizing a shape change and elasticity of the flex portion.

In the heat dissipation structure, the physical shape of the flex portion may be a length of the flex portion.

With this configuration, since the flex portion has the length to bring the at least part of the flex portion into contact with the metal case when the electronic device is assembled, the electronic device can be assembled easily by performing setting, mounting, and assembling work utilizing a shape change and elasticity of the flex portion.

In the heat dissipation structure, the at least part of the flex portion may be brought into surface-to-surface contact with the metal case.

With this configuration, since the at least part of the flex portion may be brought into surface-to-surface contact with the metal case, it is possible to increase the heat dissipation property to release the heat from the electronic component to the metal case via the flex portion.

In the heat dissipation structure, the rigid portion may include a first rigid portion and a second rigid portion, the flex portion may include an intermediate flex portion that connects the first rigid portion and the second rigid portion, and at least part of the intermediate flex portion may contact the metal case.

With this configuration, the heat generated by the electronic component mounted on the rigid portion can be released to the metal case via the intermediate flex portion connecting the two rigid portions.

In the heat dissipation structure, a substantially central portion of the intermediate flex portion may contact the metal case.

With this configuration, the heat generated by the electronic component mounted on the rigid portion can be released to the metal case via the substantially central portion of the intermediate flex portion.

In the heat dissipation structure, the first rigid portion and the second rigid portion may be provided to oppose each other, and the flex portion may include: a first end flex portion provided at an end surface of the first rigid portion; and a second end flex portion provided at an end surface of the second rigid portion.

With this configuration, the heat generated by the electronic component mounted on the rigid portion can be released to the metal case via the two end flex portions.

In the heat dissipation structure, the metal case may be connected to a ground contact portion of a metal shield connector configured to output a signal from the rigid flexible board to an outside, and the heat released to the metal case may be transmitted to a shield cable via the metal shield connector connected to the shield cable and is emitted to external air from the shield cable.

With this configuration, the heat released to the metal case can be transmitted to the shield cable via the metal shield connector connected to the shield cable and can be emitted to the external air from the shield cable.

In the heat dissipation structure, the flex portion may have a solid printed ground wiring.

With this configuration, the heat generated by the electronic component mounted on the rigid portion of the rigid flexible board or each rigid flexible board can be transmitted to the metal case efficiently.

In the heat dissipation structure, a first end of the flex portion may be provided at an end surface of the rigid portion.

With this configuration, since the flex portion provided at the end surface of the rigid flexible board, the heat generated by the electronic component mounted on the rigid portion of the rigid flexible board can be collected efficiently.

In the heat dissipation structure, a second end of the flex portion different from the first end may be a free end.

With this configuration, it is possible to provide a flex portion dedicated to heat dissipation.

In the heat dissipation structure, the second end of the flex portion may contact the metal case.

With this configuration, the heat generated by the electronic component mounted on the rigid portion can be released to the metal case via an end of the flex portion.

In the heat dissipation structure, the rigid flexible board may include a rigid layer made of a rigid material and a flexible layer made of a flexible material, the rigid portion may be formed by a multi-layer structure in which the rigid layer and the flexible layer are laminated, and the flex portion may be formed by the flexible layer extending from the rigid portion.

With this configuration, since the rigid portion and the flexible portion are integrated with each other, no connector for connecting a rigid board and a flexible board is necessary. That is, the rigid board and the flexible board can be connected to each other without using a connector.

The disclosure further provides a heat dissipation method of an electronic device, including: housing a rigid flexible board including a rigid portion and a flex portion connected to the rigid portion in a metal case such that at least part of the flex portion contacts the metal case; and dissipating heat generated by an electronic component mounted on the rigid portion to the metal case via the flex portion.

With this method, heat generated by the various electronic component mounted on the rigid portion of the rigid flexible board can be released to the metal case from the flex portion. Further, the metal case provides a shielding effect.

This application is based on and claims priority from Japanese Patent Application No. 2018-244959 filed on Dec. 27, 2018, the entire contents of which are incorporated herein by reference.

1. A heat dissipation structure of an electronic device, comprising:
a metal case; and
a rigid flexible board housed in the metal case and comprising a rigid portion and a flex portion connected to the rigid portion,
wherein at least part of the flex portion contacts the metal case to allow heat generated by an electronic component mounted on the rigid portion to be released to the metal case.

2. The heat dissipation structure of an electronic device according to claim 1,
wherein the flex portion has a physical shape to bring the at least part of the flex portion into contact with the metal case when the electronic device is assembled.

3. The heat dissipation structure of an electronic device according to claim 2,
wherein the physical shape of the flex portion is a length of the flex portion.

4. The heat dissipation structure of an electronic device according to claim 1,
wherein the at least part of the flex portion is brought into surface-to-surface contact with the metal case.

5. The heat dissipation structure of an electronic device according to claim 1,
wherein the rigid portion comprises a first rigid portion and a second rigid portion,
wherein the flex portion comprises an intermediate flex portion that connects the first rigid portion and the second rigid portion, and
wherein at least part of the intermediate flex portion contacts the metal case.

6. The heat dissipation structure of an electronic device according to claim 5,
wherein a substantially central portion of the intermediate flex portion contacts the metal case.

7. The heat dissipation structure of an electronic device according to claim 5,
wherein the first rigid portion and the second rigid portion are provided to oppose each other, and
wherein the flex portion comprises:
a first end flex portion provided at an end surface of the first rigid portion; and
a second end flex portion provided at an end surface of the second rigid portion.

8. The heat dissipation structure of an electronic device according to claim 1,
wherein the metal case is connected to a ground contact portion of a metal shield connector configured to output a signal from the rigid flexible board to an outside, and
wherein the heat released to the metal case is transmitted to a shield cable via the metal shield connector connected to the shield cable and is emitted to external air from the shield cable.

9. The heat dissipation structure of an electronic device according to claim 1,
wherein the flex portion has a solid printed ground wiring.

10. The heat dissipation structure of an electronic device according to claim 1,
wherein a first end of the flex portion is provided at an end surface of the rigid portion.

11. The heat dissipation structure of an electronic device according to claim 10,
wherein a second end of the flex portion different from the first end is a free end.

12. The heat dissipation structure of an electronic device according to claim 11,
wherein the second end of the flex portion contacts the metal case.

13. The heat dissipation structure of an electronic device according to claim 1,
wherein the rigid flexible board comprises a rigid layer made of a rigid material and a flexible layer made of a flexible material,
wherein the rigid portion is formed by a multi-layer structure in which the rigid layer and the flexible layer are laminated, and
wherein the flex portion is formed by the flexible layer extending from the rigid portion.

14. A heat dissipation method of an electronic device, comprising:
housing a rigid flexible board comprising a rigid portion and a flex portion connected to the rigid portion in a metal case such that at least part of the flex portion contacts the metal case; and
dissipating heat generated by an electronic component mounted on the rigid portion to the metal case via the flex portion.
